(19) United States
(12) Patent Application Publication
(10) Pub. No.: US 2026/0276703 A1
(43) Pub. Date: Sep. 17, 2026

(54) INSPECTION METHOD, INSPECTION APPARATUS, AND INSPECTION SYSTEM

(71) Applicant: Tokyo Electron Limited, Tokyo (JP)

(72) Inventors: Fumiya TAKASE, Nirasaki City (JP); Masahito KOBAYASHI, Nirasaki City (JP)

(21) Appl. No.: 19/648,214

(22) Filed: Apr. 15, 2026

Related U.S. Application Data
(63) Continuation of application No. PCT/JP2024/036428, filed on Oct. 11, 2024.

(30) Foreign Application Priority Data
Oct. 25, 2023 (JP) 2023-183444

(51) Int. Cl. G01R 31/311

(52) U.S. Cl. CPC G01R 31/311

(57) ABSTRACT

An inspection method includes (A) forming an assembly by fixing an inspection object and a jig substrate and (B), after (A), inspecting the inspection object by emitting inspection light from an illuminator to an imaging device of the inspection object. The jig substrate includes, in one surface, first connectors and second connectors, which are connected to the first connectors, respectively, and disposed adjacent to the first connectors. In (A), the assembly is formed by a surface of the inspection object having a pad connected to the wiring layer to face the one surface of the jig substrate so that the pad and the first connectors are connected. In (B), the inspection object is inspected that the surface of the inspection object opposite to the wiring layer in the assembly faces the illuminator and probes disposed adjacent to the illuminator are connected with the second connectors, respectively.

### CROSS-REFERENCE TO RELATED APPLICATIONS

The application is a Bypass Continuation Application of PCT International Application No. PCT/JP2024/036428, filed on Oct. 11, 2024 and designating the United States, the international application being based upon and claiming the benefit of priority from Japanese Patent Application No. 2023-183444, filed on Oct. 25, 2023, the entire contents of which are incorporated herein by reference.

### TECHNICAL FIELD

The present disclosure relates to an inspection method, an inspection apparatus, and an inspection system.

### BACKGROUND

When analyzing an inspection object (wafer) having an imaging device such as a CMOS image sensor, inspection light is irradiated from an illuminator toward a substrate to determine the presence or absence of a defect in the imaging device. Further, in recent years, for reasons such as improvement of the S/N ratio and reduction of power consumption, a back-illuminated imaging device into which light is introduced from a surface opposite to a wiring layer has been developed, and an inspection apparatus for inspecting such an imaging device has also been under development.

For example, Patent Document 1 discloses an inspection apparatus including an illuminator (light irradiator) that loads an inspection object having a back-illuminated imaging device placed on a stage and emits inspection light from the same stage side.

### Prior Art Documents

### Patent Documents

Patent Document 1: Japanese Patent Laid-open Publication No. 2020-68329

### SUMMARY

According to one embodiment of the present disclosure, there is provided an inspection method for inspecting an inspection object having an imaging device into which light is introduced from a surface opposite to a wiring layer, the inspection method including (A) forming an assembly by fixing the inspection object and a jig substrate; and (B), after the step of (A), inspecting the inspection object by emitting inspection light from an illuminator to the imaging device of the inspection object. The jig substrate includes, in one surface, a plurality of first connectors and a plurality of second connectors, which are electrically connected to the plurality of first connectors, respectively, and disposed adjacent to the plurality of first connectors. In the step of (A), the assembly is formed by causing a surface of the inspection object having a pad connected to the wiring layer to face the one surface of the jig substrate so that the pad and the plurality of first connectors are electrically connected. In the step of (B), the inspection object is inspected in a state in which the surface of the inspection object opposite to the wiring layer in the assembly faces the illuminator and a plurality of probes disposed adjacent to the illuminator are connected with the plurality of second connectors, respectively.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating a configuration of an inspection apparatus according to an embodiment.

FIG. 2A is a schematic cross-sectional view illustrating, in an enlarged manner, an imaging device inspected by the inspection apparatus according to an embodiment.

FIG. 2B is a schematic cross-sectional view illustrating, in an enlarged manner, an imaging device according to a comparative example.

FIG. 3 is a schematic side cross-sectional view illustrating, in an enlarged manner, an inspection state of a wafer of an assembly in the inspection apparatus.

FIG. 4 is a block diagram schematically illustrating an inspection system according to an embodiment.

FIG. 5 is a schematic side view illustrating fabrication of an assembly by a positioning and fixing apparatus.

FIG. 6 is a flowchart illustrating a method for inspecting a wafer having respective imaging devices according to an embodiment.

FIG. 7A is a side cross-sectional view schematically illustrating an assembly according to a first modification.

FIG. 7B is a side cross-sectional view schematically illustrating an assembly according to a second modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure will be described with reference to the drawings. In each drawing, the same reference numerals may be given to the same components, and redundant descriptions may be omitted.

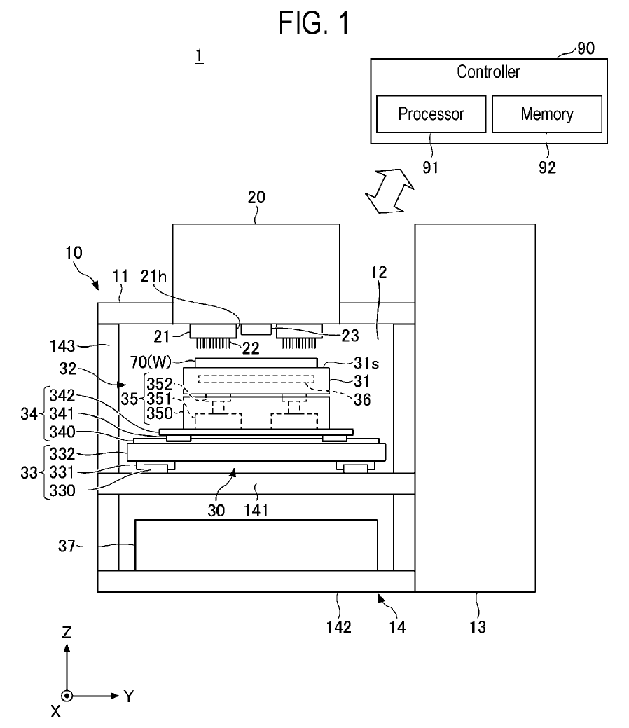

FIG. 1 is a schematic cross-sectional view illustrating a configuration of an inspection apparatus 1 according to an embodiment. As illustrated in FIG. 1, the inspection apparatus 1 according to the embodiment is an apparatus that optically inspects an inspection object having an imaging device. The inspection object inspected by the inspection apparatus 1 is, for example, a substrate (hereinafter referred to as "wafer W") formed in a perfect circular shape in a plan view and having a plurality of imaging devices arranged in a matrix. In addition, the inspection object is not limited to the wafer W, but may be, e.g., a carrier on which a plurality of imaging devices or a single imaging device is disposed or an electronic circuit board.

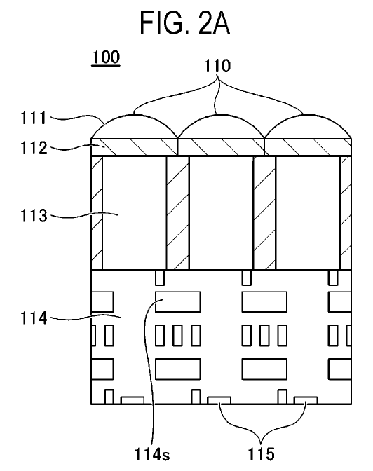

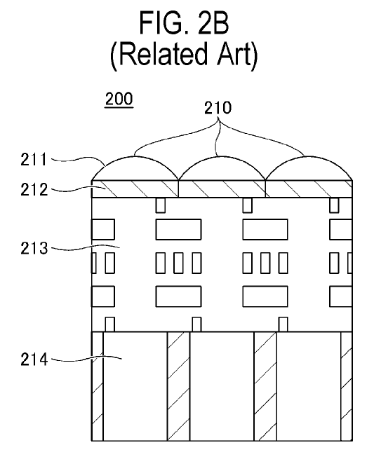

FIG. 2A is a schematic cross-sectional view illustrating, in an enlarged manner, an imaging device 100 inspected by the inspection apparatus 1 according to an embodiment. FIG. 2B is a schematic cross-sectional view illustrating, in an enlarged manner, an imaging device 200 according to a comparative example. As illustrated in FIG. 2A, an example of the plurality of imaging devices 100 inspected by the inspection apparatus 1 may include solid-state imaging elements using a complementary metal oxide semiconductor (CMOS). Each CMOS imaging device 100 is composed of, for each pixel 110 arranged in a grid pattern, one photodiode 113 and a switch 114s of a CMOS transistor, and performs direct readout by switching the switch 114s to amplify signals for each pixel 110.

However, the performance of each imaging device 100 varies depending on the arrangement of a stacked structure constituting the pixel 110. Hereinafter, to facilitate the understanding of the imaging device 100 according to the embodiment, the imaging device 200 according to the comparative example (the related art) will first be described with reference to FIG. 2B.

A plurality of pixels 210 of the imaging device 200 according to the comparative example detect a color (for example, any one of RGB colors) registered in a color filter 212 stacked on an upper layer of a photodiode 214. Each pixel 210 is formed in a stacked structure in which an on-chip lens 211, the color filter 212, a wiring layer 213, and the photodiode 214 are stacked in this order.

In other words, in the imaging device 200, the wiring layer 213 is disposed between the color filter 212 and the photodiode 214. Inspection light introduced from the on-chip lens 211 passes through the color filter 212 and the wiring layer 213 and enters the photodiode 214. In this case, since a pad (not illustrated) connected to the wiring layer 213 may be disposed on the on-chip lens 211 side, the inspection apparatus may perform inspection by arranging, in the same direction, an illuminator that emits the inspection light onto the imaging device 200 and each probe that comes into contact with the pad. However, since the inspection light passes through the wiring layer 213, the photodiode 214 of the imaging device 200 receives the inspection light that has incurred a significant loss.

On the other hand, as illustrated in FIG. 2A, a plurality of pixels 110 of the imaging device 100 are formed in a stacked structure in which an on-chip lens 111, a color filter 112, a photodiode 113, and a wiring layer 114 are stacked in this order. That is, the stacking order of the photodiode 113 and the wiring layer 114 in the imaging device 100 is reversed relative to the stacking order of the wiring layer 213 and the photodiode 214 of the imaging device 200.

In the imaging device 100, the photodiode 113 is disposed on a rear surface of the color filter 112. Inspection light introduced from the on-chip lens 111 enters the photodiode 113 immediately after passing through the color filter 112. In this case, the imaging device 100 may receive the inspection light in the photodiode 113 without obstruction by the wiring layer 114, which causes a significant improvement in detection sensitivity. Further, in the imaging device 100, an electrode pad (including, e.g., a semiconductor bump) 115 connected to the wiring layer 114 is disposed on a surface opposite to the on-chip lens 111.

However, as illustrated in FIG. 1, the inspection apparatus 1 is configured to move the wafer W placed on a stage 30 and inspect the wafer W at an inspection position. Further, it is desirable that the inspection apparatus 1 includes, such as a temperature adjustment module 36 for adjusting the temperature of the wafer W in an interior of the stage 30. Therefore, providing an illuminator 23 for emitting inspection light onto the imaging device 100 on the stage 30 side would significantly alter a general configuration of the stage 30.

Thus, the inspection apparatus 1 according to the embodiment is configured such that the illuminator 23 is installed on the same side as each probe 22 of a tester 20, while no illuminator is installed on the stage 30 side. Hereinafter, a configuration of the inspection apparatus 1 will be described in detail with reference to FIG. 1.

The inspection apparatus 1 includes an inspector 10 that actually performs an inspection, a loader 13 installed adjacent to the inspector 10, and the tester 20 installed above the inspector 10. Furthermore, the inspection apparatus 1 includes a controller 90 serving as a control part that controls operations of the inspector 10, the loader 13, and the tester 20.

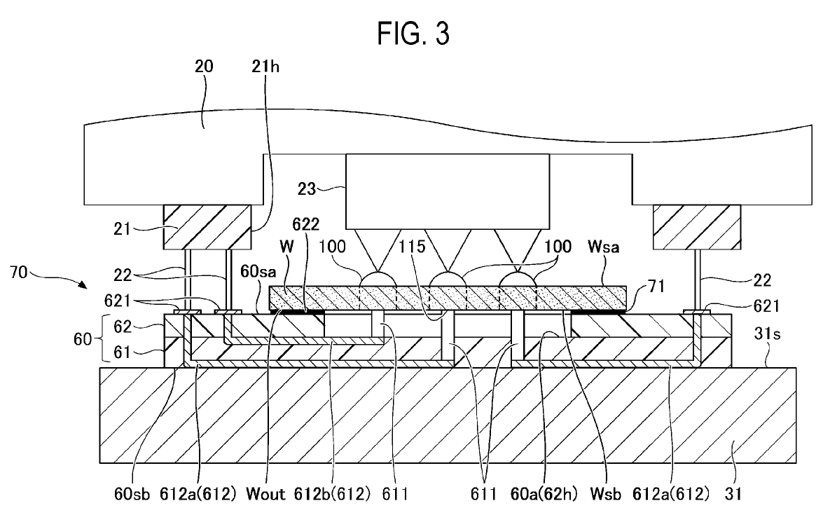

The inspector 10 includes a rectangular housing 11, and an inspection chamber 12 is provided in the interior of the housing 11. The inspection chamber 12 accommodates the stage 30 for transporting the wafer W. In addition, in the inspection apparatus 1 according to the embodiment, the wafer W is formed as an assembly 70 integrated with a jig substrate 60 (see FIG. 3) to be described later, and is placed on the stage 30. A configuration of the assembly 70 will be described in detail later.

A carrier such as a front-opening unified pod (FOUP) (not illustrated) for holding a plurality of assemblies 70 on standby is set in the loader 13. The loader 13 includes a transport device (not illustrated), and the transport device takes out the assembly 70 from the carrier and transfers the assembly 70 to the stage 30 in the inspection chamber 12. Further, the loader 13 takes out the completely inspected assembly 70 from the stage 30 by the transport device and accommodates the assembly 70 in the carrier.

The inspector 10 includes a probe card 21, which is connected to the tester 20, above the inspection chamber 12. The probe card 21 includes a plurality of probes 22 on a lower surface in the vertical direction. The respective probes 22 come into contact with respective pads 621 (see FIG. 3) of the assembly 70 when the assembly 70 is moved by the stage 30. Thereby, the tester 20 receives electrical signals transmitted from the wafer W of the assembly 70 via the probe card 21.

The tester 20 includes a motherboard (not illustrated) electrically connected to the probe card 21 inside the tester 20. The motherboard has a plurality of slots into which a plurality of test boards (not illustrated) are mounted, and is connected to the controller 90. The motherboard determines the quality of each imaging device 100 based on electrical signals transmitted from the wafer W. The tester 20 may perform a plurality of types of inspections by appropriately replacing the test boards.

Further, the tester 20 includes the illuminator 23 that emits inspection light onto the wafer W of the assembly 70 through a hole 21h provided in a central portion of the probe card 21. In other words, the probe card 21 arranges the respective probes 22 so as to surround the periphery of the hole 21h.

The illuminator 23 includes a light source module serving as a light source of inspection light, and a lens module disposed in an emission direction (on an optical axis) of inspection light from the light source module (both not illustrated). The light source module includes, for example, a plurality of light emitting diodes (LEDs) (not illustrated) that emit inspection light downward in the vertical direction, and is electrically connected to the controller 90. When inspecting a plurality of colors in the imaging device 100, the light source module may be configured to emit inspection light of a single color (for example, white), or may be configured to emit inspection light of a plurality of colors (for example, red, green, and blue).

The lens module is a module that reproduces a lens portion of an imaging mechanism (not illustrated) such as a camera in which the imaging device 100 is included, and is also referred to as "pupil module" (registered trademark). The inspection apparatus 1 is capable of reproducing an environment in which the imaging device 100 is actually used by using the lens module for inspection, thereby enabling inspection of whether specifications defined under the environment may be exhibited. As an example, since most of cameras mounted in smartphones have different numbers and shapes of lenses depending on the smartphone model, the lens module is designed according to the lens specifications of each camera and is replaced depending on inspection contents. The lens module includes, for example, a plurality of lenses arranged in a matrix, each lens having a convex surface facing downward in the vertical direction, thereby making it possible to maintain uniformity of the light intensity of inspection light transmitted through the respective lenses.

On the other hand, the stage 30 is installed in the inspection chamber 12 below the probe card 21 (the respective probes 22) and the illuminator 23 of the tester 20 in the vertical direction. The stage 30 transports the assembly 70 placed on a placement surface 31s to an appropriate three-dimensional coordinate position (X-axis direction, Y-axis direction and Z-axis direction) in the inspection chamber 12. For example, the stage 30 moves in the horizontal direction (X-axis and Y-axis directions) between a position in the vicinity of (or inside) the loader 13 and a position facing the probe card 21 to adjust a horizontal position of the assembly 70. Further, the stage 30 moves in the vertical direction (Z-axis direction) at a position at which the probe card 21 and the assembly 70 face each other, thereby adjusting a height position of the assembly 70.

The stage 30 includes a placement table 31 having the flat placement surface 31s capable of supporting the assembly 70, a mover 32 (an X-axis moving mechanism 33, a Y-axis moving mechanism 34, and a Z-axis moving mechanism 35), and a stage controller 37. In addition, the stage 30 may include, e.g., a stage-side camera (not illustrated) for imaging, e.g., a contact state between the probe card 21 or the respective probes 22 and the assembly 70.

According to the stage 30, a frame structure 14 of the housing 11 has a two-stage structure including an upper base 141 that supports the mover 32, a lower base 142 that supports the stage controller 37, and a plurality of posts 143 that extend in the vertical direction to support the upper base 141 and the lower base 142.

The placement table 31 is configured by stacking a plurality of structures such as a bottom plate supported by the mover 32 and a chuck top having the placement surface 31s. The placement surface 31s of the chuck top has a circular shape in a plan view with a larger diameter than that of the assembly 70. In addition, the assembly 70 is not limited to being formed in a circular shape in a plan view, but may have, for example, a rectangular shape or another polygonal shape. The placement surface 31s of the chuck top is also not limited to a circular shape, but may be formed in a rectangular shape or another polygonal shape according to the planar shape of the assembly 70.

Further, the placement table 31 includes the temperature adjustment module 36 for adjusting the temperature of the assembly 70 placed on the placement surface 31s inside the placement table 31. Further, although not illustrated, the stage 30 includes, e.g., a lifter mechanism that raises and lowers the assembly 70 to receive and transfer the assembly 70 from and to the transport device of the loader 13, and a θ rotation mechanism (not illustrated) that rotates the chuck top around a central axis (θ axis). Furthermore, the chuck top may include, e.g., a holder (for example, a vacuum suction mechanism or a mechanical chuck) for holding the wafer W on the placement surface 31s, and a temperature sensor for detecting the temperature of the placement surface 31s.

The X-axis moving mechanism 33 of the mover 32 includes a plurality of guide rails 330 fixed to an upper surface of the upper base 141 and extending along the X-axis direction, a plurality of X-axis movable bodies 331 disposed on the respective guide rails 330, and an X-axis table 332 supported by the respective X-axis movable bodies 331. The X-axis table 332 includes an X-axis drive (not illustrated) (such as a motor and a gear mechanism) connected to the stage controller 37. The X-axis drive adjusts an X coordinate of the assembly 70 by reciprocating the respective X-axis movable bodies 331 and the X-axis table 332 in the X-axis direction based on power supplied from the stage controller 37.

The Y-axis moving mechanism 34 includes a plurality of guide rails 340 fixed to an upper surface of the X-axis table 332 and extending along the Y-axis direction, a plurality of Y-axis movable bodies 341 disposed on the respective guide rails 340, and a Y-axis table 342 supported by the respective X-axis movable bodies 341. The Y-axis table 342 includes a Y-axis drive (not illustrated) (such as a motor and a gear mechanism) connected to the stage controller 37. The Y-axis drive adjusts an Y coordinate of the assembly 70 by reciprocating the respective Y-axis movable bodies 341 and the Y-axis table 342 in the Y-axis direction based on power supplied from the stage controller 37.

The Z-axis moving mechanism 35 is installed on the Y-axis table 342 and supports the bottom plate of the placement table 31 at the top thereof. The Z-axis moving mechanism 35 includes a fixed guide body 350, a plurality of Z-axis drives 351, and a Z-axis movable body 352 that moves vertically along the fixed guide body 350 under driving of the respective Z-axis drives 351. Each Z-axis drive 351 independently raises and lowers the Z-axis movable body 352 based on power supplied from the stage controller 37, thereby adjusting a Z coordinate of the assembly 70.

The stage controller 37 of the stage 30 is connected to the controller 90 of the inspection apparatus 1, and controls a motor driver (not illustrated) based on commands from the controller 90 to operate the stage 30. The stage controller 37 includes, for example, a main controller that controls an overall operation of the stage 30, a programmable logic controller (PLC) that controls an operation of the mover 32, a temperature controller that controls the temperature adjustment module 36, an illumination controller, and a power supplier (all not illustrated). After receiving the assembly 70 from the loader 13 onto the placement table 31, the stage controller 37 operates the mover 32 to move the assembly 70 in the horizontal direction. Furthermore, the stage controller 37 raises the assembly 70 at a position facing the probe card 21 to bring the assembly 70 into contact with the respective probes 22 of the probe card 21. In this state, the controller 90 starts inspection by the tester 20. Further, after completion of inspection by the tester 20, the stage controller 37 lowers and horizontally moves the inspected wafer W by an operation reverse to that described above, and returns the wafer W to the loader 13.

The controller 90 of the inspection apparatus 1 is a computer including, e.g., a processor 91, a memory 92, an input/output interface (not illustrated), and a communication interface (not illustrated). The processor includes one or a combination of two or more of a central processing unit (CPU), a graphics processing unit (GPU), an application specific integrated circuit (ASIC), a field-programmable gate array (FPGA), and a circuit composed of a plurality of discrete semiconductors, and executes computer readable programs stored in the memory. The memory includes a main storage device including a semiconductor memory and an auxiliary storage device composed of, e.g., a disk and a semiconductor memory (flash memory).

FIG. 3 is a schematic side cross-sectional view illustrating, in an enlarged manner, an inspection state of the wafer W of the assembly 70 in the inspection apparatus 1. Next, the assembly 70 inspected by the inspection apparatus 1 according to the embodiment will be described with reference to FIG. 3. The assembly 70 is formed by preparing the jig substrate 60 in addition to the wafer W, and fixing a lower surface Wsb of the wafer W on the wiring layer 114 side to one surface of the jig substrate 60, that is, an upper surface 60sa.

The jig substrate 60 has a larger planar shape than the wafer W (that is, a diameter larger than a diameter of the wafer W). The jig substrate 60 protrudes radially outward beyond an outer edge of the wafer W in a state in which the wafer W and the jig substrate 60 are fixed to each other. In inspection of the inspection apparatus 1, the jig substrate 60 positions each imaging device 100 of the wafer W at a position facing the illuminator 23 of the tester 20, while positioning a protruding portion of the jig substrate 60 at a position facing the probe card 21. Further, a lower surface 60sb of the jig substrate 60 is formed in a flat shape, so that the assembly 70 is stably placed on the placement surface 31s of the stage 30.

The jig substrate 60 is configured by stacking a first substrate 61 having a continuously extending flat plate shape and an annular second substrate 62 having a hole 62h at a central portion. The first substrate 61 and the second substrate 62 are made of the same material and are inseparably joined by a joining method such as welding, bonding, or mechanical engagement. In addition, the jig structure 60 is not limited to a configuration formed by a plurality of components (the first substrate 61 and the second substrate 62), but may be formed by a single component. By stacking the first substrate 61 and the second substrate 62, a recess 60a corresponding to the hole 62h of the second substrate 62 is formed at a central portion of the upper surface 60sa of the jig substrate 60.

The first substrate 61 is formed in a circular shape in a plan view, and is made of an insulating material such as a resin material. The first substrate 61 has a plurality of jig probes 611 (first connectors) that protrude toward an opening direction (vertically upward) of the recess 60a at a central portion of the jig substrate 60 (a portion facing the hole 62h of the second substrate 62). The plurality of jig probes 611 protrude inside the recess 60a. Each jig probe 611 is made of a conductive material such as a metal, and a protruding end of the jig probe 611 comes into contact with the electrode pad 115 (see FIG. 2A) which is connected to the wiring layer 114 of each imaging device 100 in a state in which the jig substrate 60 and the wafer W are fixed. Thereby, each jig probe 611 may be electrically connected to each imaging device 100.

The second substrate 62 is formed in an annular shape in a plan view, and is also made of an insulating material such as a resin material. The second substrate 62 includes a surface constituting the upper surface 60sa of the jig substrate 60 (a surface opposite to a surface fixed to the first substrate 61). The second substrate 62 also has a jig substrate facing portion 622 facing the wafer W at a position radially outward of the hole 62h. The jig substrate facing portion 622 annularly surrounds the hole 62h. A fixture 71 for fixing an inspection object side outer peripheral portion Wₒᵤₜ, which is an outer peripheral portion on the lower surface Wsb side of the wafer W, is provided on the jig substrate facing portion 622.

Furthermore, the second substrate 62 has a plurality of pads 621 (second connectors) at positions radially outward of the jig substrate facing portion 622. The plurality of pads 621 are made of a conductive material such as a metal, and are provided along the circumferential direction of the outer periphery of the second substrate 62 in the same number as that of the plurality of jig probes 611. The plurality of pads 621 electrically connected to the respective probes 22 of the probe card 21 by connecting the respective probes 22 during inspection.

Then, the jig substrate 60 further includes a plurality of wires 612 that electrically connect the plurality of jig probes 611 and the plurality of pads 621, respectively. For example, each wire 612 includes a wire 612a extending along a lower surface of the first substrate 61 (the lower surface 60sb of the jig substrate 60), or a wire 612b extending along an upper surface of the first substrate 61 (a boundary surface with the second substrate 62). Further, each wire 612 is not limited to a configuration in which it is exposed from and extends along the lower or upper surface of the first substrate 61, but may alternatively extend inside the substrate.

One end of each wire 612 is connected to a corresponding one of the jig probes 611, while the other end of each wire 612 is connected to a corresponding one of the pads 621. The respective wires 612 extend while being spaced apart from one another, thereby remaining electrically isolated from each other. In other words, the respective jig probes 611, the respective wires 612, and the respective pads 621 are in a 1:1:1 correspondence relationship, continuously connecting a central portion and an outer peripheral portion of the jig substrate 60.

In the jig substrate 60 configured as described above, the fixture 71 for fixing the lower surface Wsb of the wafer W is provided on the jig substrate facing portion 622, which surrounds the recess 60a in the upper surface 60sa. It is sufficient that an adhesive having an appropriate bonding force be applied to the fixture 71, such that the wafer W before inspection is fixed without positional misalignment, while the wafer W after inspection is removable. The type of the fixture 71 is not particularly limited, but, for example, MicroSpheres (registered trademark) may be used. In addition, the fixture 71 is not limited to an adhesive, but may appropriately use, for example, a configuration in which the wafer W and the jig substrate 60 are mechanically engaged, or a configuration in which they are temporarily welded. As an example, the jig substrate 60 may have the recess 60a having the same diameter as the diameter of the wafer W, into which the outer edge of the wafer W is fitted and fixed.

It becomes possible to handle the assembly 70 as an integrated member by fixing the wafer W and the jig substrate 60 together. At the time of fixing, the jig probes 611 protruding into the recess 60a respectively contact and contact with the electrode pads 115 of each imaging device 100 of the wafer W. Thereby, the assembly 70 has a wiring structure in which an electrical connection is established from each imaging device 100 of the wafer W to the respective pads 621 provided radially outward of the wafer W.

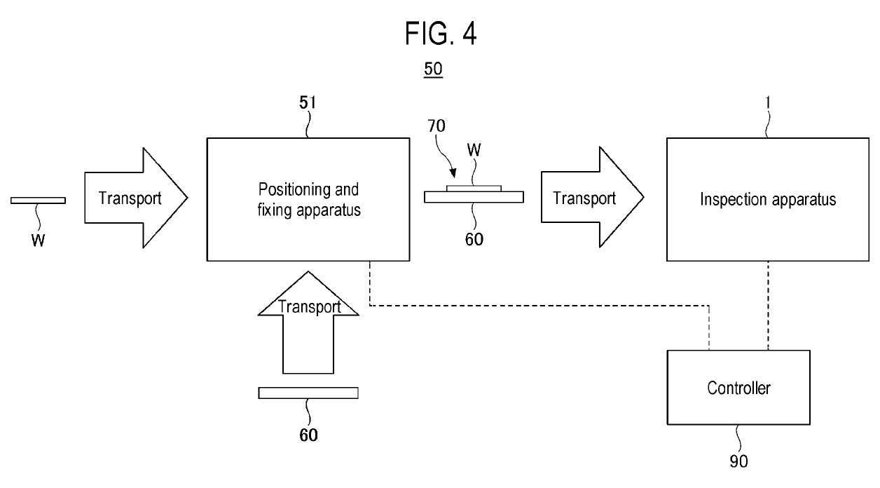

Here, when forming the assembly 70, it is necessary to accurately align the wafer W and the jig substrate 60 to fix the wafer W and the jig substrate 60. Therefore, as illustrated in FIG. 4, in the present embodiment, an inspection system 50 including the inspection apparatus 1 and a positioning and fixing apparatus 51 is constructed, and the assembly 70 is formed before the wafer W is inspected in the inspection apparatus 1. FIG. 4 is a block diagram schematically illustrating the inspection system 50 according to an embodiment. In addition, the controller 90 of the inspection apparatus 1 may be applied as a control part that controls the entire inspection system 50. Alternatively, the inspection system 50 may include respective control parts for the positioning and fixing apparatus 51, the inspection apparatus 1, and each transport robot, such that each control part performs independent control (or cooperated control through information communication).

In the inspection system 50, a transport robot (not illustrated) is used to first transport the wafer W and the jig substrate 60 to the positioning and fixing apparatus 51, and the positioning and fixing apparatus 51 fixes the wafer W and the jig substrate 60 together to fabricate the assembly 70. Thereafter, the inspection system 50 uses the transport robot to transport the assembly 70 from the positioning and fixing apparatus 51 to the inspection apparatus 1, and the inspection apparatus 1 inspects the wafer W of the assembly 70. In addition, the inspection system 50 is not limited to a configuration in which the wafer W and the jig substrate 60 are fixed by the positioning and fixing apparatus 51, but, for example, an operator may manually fabricate the assembly 70. In this case, the operator may perform positioning of the wafer W and the jig substrate 60 using a dedicated positioning jig (not illustrated).

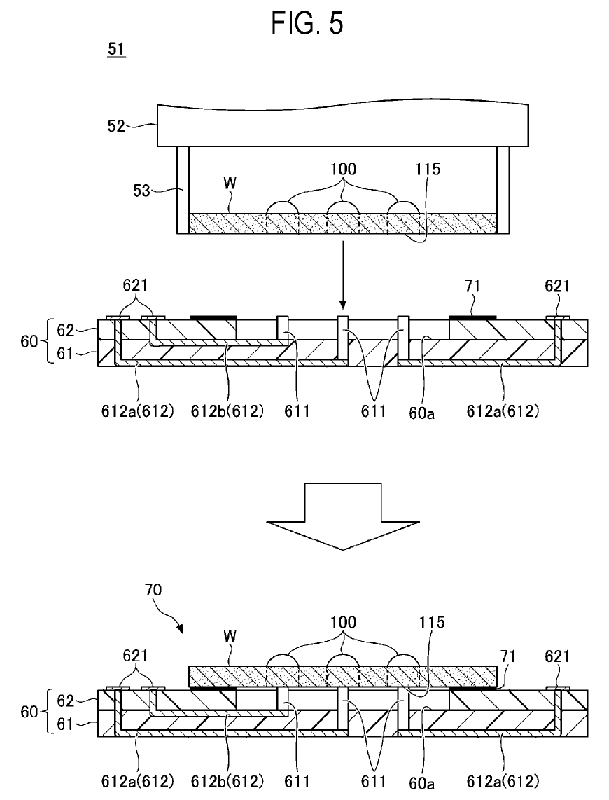

FIG. 5 is a schematic side view illustrating the fabrication of the assembly 70 by the positioning and fixing apparatus 51. As illustrated in FIG. 5, the positioning and fixing apparatus 51 performs positional alignment between the wafer W and the jig substrate 60 before fixing, and then fixes the wafer W and the jig substrate 60 together by bringing the lower surface Wsb of the wafer W into contact with the upper surface 60sa of the jig substrate 60.

For example, the positioning and fixing apparatus 51 includes a hand mechanism 52 that grips the outer edge of the wafer W by a plurality of claws 53. Further, the positioning and fixing apparatus 51 includes an imaging part (not illustrated) that detects and recognizes a position of each jig probe 611 of the jig substrate 60 and a position of each imaging device 100 of the wafer W. The positioning and fixing apparatus 51 moves the hand mechanism 52 gripping the wafer W to an appropriate horizontal coordinate position and rotates it around an axis based on the recognized positions, thereby positionally aligning each jig probe 611 with the electrode pad 115 (see FIG. 2A) of each imaging device 100. Further, the hand mechanism 52 lowers the position-aligned wafer W toward the jig substrate 60, thereby fixing the inspection object side outer peripheral portion Wₒᵤₜ of the lower surface Wsb of the wafer W to the fixture 71 of the jig substrate 60. Thereby, the positioning and fixing apparatus 51 may obtain the assembly 70 in which the wafer W and the jig substrate 60 are integrated, with each electrode pad 115 accurately brought into contact with a corresponding one of the jig probes 611.

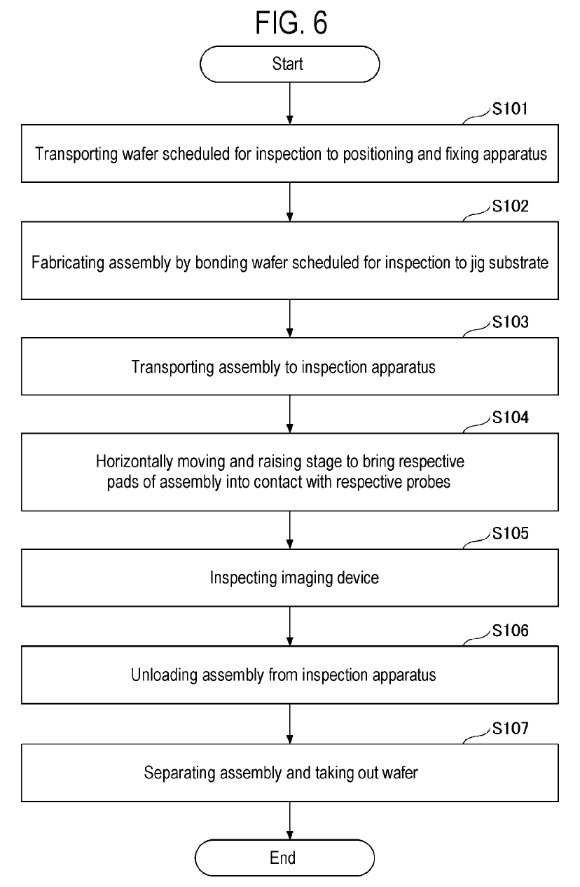

The inspection apparatus 1 and the inspection system 50 according to the embodiment are basically configured as described above. Next, an inspection method for inspecting the wafer W will be described with reference to FIG. 6. FIG. 6 is a flowchart illustrating an inspection method for inspecting the wafer W having each imaging device 100 according to an embodiment.

In the inspection method of the wafer W, the control part (controller 90) of the inspection system 50 controls the positioning and fixing apparatus 51, the inspection apparatus 1, and the transport robot to perform steps S101 to S107 illustrated in FIG. 6.

In the inspection method, the controller 90 first controls the transport robot to transport the wafer W scheduled for inspection to the positioning and fixing apparatus 51 (step S101). In addition, the inspection system 50 transports the jig substrate 60 to the positioning and fixing apparatus 51 in advance, either before or after transporting the wafer W.

Next, the controller 90 controls the positioning and fixing apparatus 51 to bond the wafer W scheduled for inspection and the jig substrate 60, thereby fabricating the assembly 70 (step S102). For example, the positioning and fixing apparatus 51 performs positional alignment between the wafer W and the jig substrate 60, and then lowers the wafer W onto the jig substrate 60, as illustrated in FIG. 5. Thereby, the lower surface Wsb of the wafer W and the upper surface 60sa of the jig substrate 60 are fixed at the fixture 71, which prevents positional misalignment of the wafer W relative to the jig substrate 60.

Thereafter, the controller 90 controls the transport robot to transport the fabricated assembly 70 to the inspection apparatus 1 (step S103). Then, after the assembly 70 has been transported, the controller 90 proceeds to inspection of the wafer W of the assembly 70 by the inspection apparatus 1. At this time, the inspection apparatus 1 may adjust the stage 30 (the temperature adjustment module 36) to a target temperature in advance under the control of the controller 90.

After the assembly 70 is placed on the stage 30 by the transport device of the loader 13, the inspection apparatus 1 horizontally moves and raises the stage 30 under the control of the stage controller 37, so that the respective pads 621 of the assembly 70 come into contact with the respective probes 22 (step S104). As illustrated in FIG. 3, the respective probes 22 correspond to positions of the respective pads 621 of the jig substrate 60. The stage 30 first horizontally moves the assembly 70 to a position at which the pads 621 respectively face the probes 22, and then raises the assembly 70 until all of the pads 621 come into contact with all of the probes 22. This may ensure reliable contact between the respective probes 22 and the respective pads 621. Further, in a state in which the assembly 70 is in contact with the respective probes 22, each imaging device 100 of the wafer W and the illuminator 23 face each other in the vertical direction and are sufficiently close to each other.

In this state, the inspection apparatus 1 operates the tester 20 to inspect each imaging device 100 of the wafer W under the control of the controller 90 (step S105). The tester 20 emits inspection light from the illuminator 23 onto the wafer W. Each imaging device 100 of the wafer W receives the inspection light sequentially through the on-chip lens 111, the color filter 112, and the photodiode 113 (see FIG. 2A), thereby outputting appropriate electrical signals from the electrode pad 115 of the wiring layer 114. As illustrated in FIG. 3, upon receiving the electric signals via the respective jig probes 611, the jig substrate 60 transmits the electrical signals to the respective wires 612 and the respective pads 621, and outputs them to the respective probes 22 that are in contact with the pads 621. Thereby, the tester 20 is capable of obtaining inspection results of each imaging device 100 via the respective probes 22 and the probe card 21.

After the inspection of the wafer W is completed, the inspection apparatus 1 unloads the assembly 70 (step S106). The stage 30 separates the assembly 70 from the respective probes 22 by an operation reverse to that performed before inspection, and transfers the assembly 70 to the transport device of the loader 13. Then, the controller 90 causes the transport robot of the inspection system 50 to unload the assembly 70 out of the inspection apparatus 1.

Finally, the inspection system 50 separates the wafer W and the jig substrate 60 of the assembly 70 and takes out the wafer W (step S107). This processing may be performed automatically by transporting the assembly 70 to a separation device (not illustrated), or alternatively may be performed manually by the operator after transporting the assembly 70 to a processing position (not illustrated).

The inspection method enables stable inspection of each imaging device 100 of the wafer W according to the above processing flow. The inspection apparatus 1 according to the embodiment does not require a configuration for backside irradiation of the wafer W (i.e., a configuration in which the illuminator 23 and the respective probes 22 are disposed on opposite sides with the wafer W interposed therebetween), and thus, the stage 30 (prober device), which is generally used, may be used. Further, the jig substrate 60 has a sufficiently small thickness to facilitate temperature transfer from the stage 30 to the wafer W. Therefore, the inspection apparatus 1 may smoothly adjust the temperature of the wafer W to a target temperature by the temperature adjustment module 36 in the placement table 31.

However, in a configuration in which surface irradiation is performed on the imaging device 100 (i.e., a configuration in which the illuminator 23 and the respective probes 22 are arranged on the same side), it is also conceivable to dispose the respective pads 621 that come into contact with the respective probes 22 at positions spaced apart in the horizontal direction from the wafer W having each imaging device 100. However, if the wafer W is spaced apart from the respective pads 621 in this manner, a chuck for supporting the respective pads 621 would be required in addition to a chuck for supporting the wafer W, resulting in an increase in the size of the stage 30. In contrast, in the jig substrate 60 according to the embodiment, the respective pads 621 may be arranged in the vicinity of the wafer W and along the entire circumferential direction of the wafer W, allowing the assembly 70 to be supported by only one chuck. Accordingly, the stage 30 may be downsized, thereby improving the footprint of the inspection apparatus 1. Furthermore, for example, compared to a configuration in which the respective pads 621 are arranged at positions horizontally distant from the wafer W, the assembly 70 may shorten the wiring length from the electrode pad 115 of the wafer W to each pad 621 of the jig substrate 60. As a result, it is possible to reduce electrical noise and improve inspection accuracy during inspection of the wafer W.

In addition, the inspection method, the inspection apparatus 1, and the inspection system 50 according to the present disclosure are not limited to the above-described embodiments and may be modified in various ways. For example, the jig substrate 60 according to the embodiment is configured to have the recess 60a and the jig probes 611. However, the configuration is not limited thereto, and the jig substrate 60 may instead be formed in a flat shape without the recess 60a, but may have connectors (such as pads, conductive sheets, or conductive adhesives) that come into contact with the electrode pad 115 of each imaging device 100 of the wafer W.

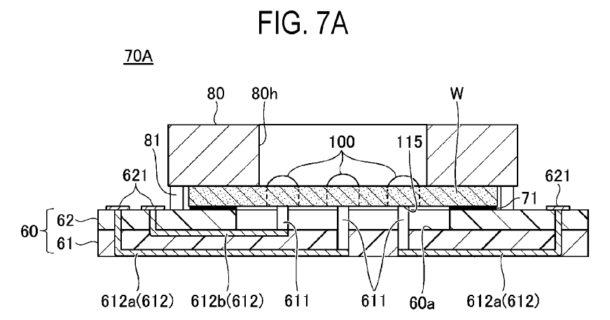

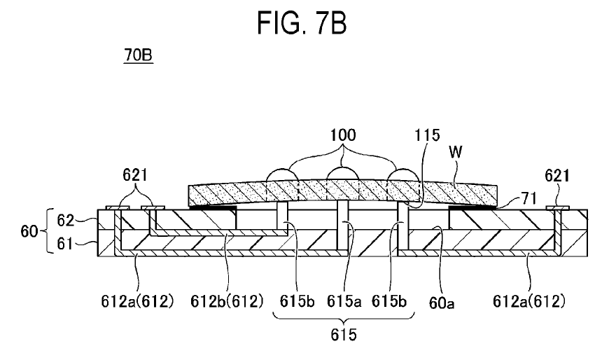

FIG. 7A is a side cross-sectional view schematically illustrating an assembly 70A according to a first modification. FIG. 7B is a side cross-sectional view schematically illustrating an assembly 70B according to a second modification. As illustrated in FIG. 7A, the assembly 70A according to the first modification differs from the assembly 70 according to the above-described embodiment in that a deformation preventing member 80 is stacked on the upper surface Wsa side of the wafer W. In addition, in the following description of the modifications, components that are identical to or have the same functions as those of the assembly 70 according to the embodiment are denoted by the same reference numerals, and detailed descriptions thereof are omitted.

The deformation preventing member 80 is stacked at a position opposite to the jig substrate 60 (i.e., on the upper surface Wsa of the wafer W) with the wafer W interposed therebetween, thereby preventing deformation of the wafer W due to a contact load in a state in which the respective jig probes 611 of the jig substrate 60 come into contact with the wafer W. Thereby, even if the respective jig probes 611 apply a large contact load to the wafer W, it is possible to prevent damage to the wafer W (for example, deformation of an outer peripheral portion of the wafer W) or peeling (release of fixation) from the jig substrate 60.

For example, the deformation preventing member 80 is made of a material harder than the wafer W, and has a through-hole 80h (or a recess) in a central portion facing each imaging device 100 of the wafer W. The through-hole 80h serves as an optical path for guiding inspection light from the illuminator 23 to each imaging device 100 during inspection of the wafer W. The deformation preventing member 80 may further include a fixing protrusion 81 for positioning with respect to the jig substrate 60 and for fixing to the jig substrate 60 when stacked on the wafer W.

In addition, the deformation preventing member 80 may be made of a material such as glass that is capable of transmitting inspection light. In this case, the deformation preventing member 80 may guide inspection light to each imaging device 100 even without providing the through-hole 80h. Alternatively, the deformation preventing member 80 may have a recess (not illustrated) in order to avoid contact with the on-chip lens 111.

The assembly 70B according to the second modification illustrated in FIG. 7B differs from the assemblies 70 and 70A in that it includes respective jig probes 615 capable of controlling a contact load applied to the wafer W. For example, in the assembly 70B, the protruding length of a jig probe 615a located at a central portion is set longer than the protruding length of a jig probe 615b located at an outer peripheral portion. The protruding lengths of the jig probes 615a and 615b may be designed in advance based on a calculated warp of the wafer W in accordance with the expected curvature. Thereby, the respective jig probes 615 are capable of applying a uniform contact load over the entire wafer W, thereby stabilizing the contact state between the respective electrode pads 115 of the wafer W and the respective jig probes 615.

In addition, adjustment of the contact load applied to the wafer W is not limited to varying the protruding lengths of the respective jig probes 615. For example, the contact load may also be adjusted by varying the spring force of the respective jig probes 615 according to the positions (e.g., stronger at the central portion and weaker at the outer peripheral portion).

The technical ideas and effects of the present disclosure described in the above embodiments will be described below.

A first embodiment of the present disclosure is the inspection method for inspecting an inspection object (wafer W) having an imaging device 100 into which light is introduced from the surface (upper surface Wsa) opposite to the wiring layer 114, the inspection method including (A) forming the assembly 70 by fixing the inspection object and the jig substrate 60, and (B), after the step of (A), inspecting the inspection object by emitting inspection light from the illuminator 23 to the imaging device 100 of the inspection object, wherein the jig substrate 60 includes, in one surface (upper surface 60sa), the plurality of first connectors (jig probes 611) and the plurality of second connectors (pads 621), which are electrically connected to the plurality of first connectors, wherein, in the step of (A), the assembly 70 is formed by causing the surface (lower surface Wsb) of the inspection object having the pad (electrode pad 115) connected to the wiring layer 114 to face the one surface of the jig substrate 60 so that the pad (electrode pad 115) and the plurality of first connectors are electrically connected, and wherein, in the step of (B), the inspection object is inspected in a state in which the surface of the inspection object opposite to the wiring layer in the assembly 70 faces the illuminator 23 and the plurality of probes 22 disposed adjacent to the illuminator 23 are connected with the plurality of second connectors, respectively.

According to the above, in the inspection method, the inspection of the inspection object can be smoothly performed with a simple configuration by fabricating the assembly 70 in which the inspection object (wafer W) and the jig substrate 60 are fixed together. That is, the assembly 70 is moved relative to the tester 20, in which the plurality of probes 22 and the illuminator 23 are arranged in the same direction, by using the stage 30 having a configuration similar to that of a stage generally used. Then, in the inspection method, in a state in which the probes 22 are brought into contact with the plurality of second connectors (pads 621), respectively, the inspection light is emitted from the illuminator 23 and an electric signal of the imaging device 100 is acquired via the plurality of probes 22, whereby the imaging device 100 can be inspected in a stable manner.

Further, in the jig substrate 60, the plurality of second connectors (pads 621) are arranged to surround the plurality of first connectors (jig probes 611). Thereby, in the assembly 70 in which the inspection object (wafer W) and the jig substrate 60 are fixed together, the plurality of second connectors (pads 621) can be arranged in a vicinity of the inspection object, which makes it possible to shorten the wiring length and thereby reduce, e.g., noise.

Further, the jig substrate 60 has a larger planar shape than the inspection object (wafer W), and, wherein the step of (A), the inspection object and the jig substrate 60 are stacked by overlapping the imaging device 100 of the inspection object with respect to the plurality of first connectors (jig probes 611), thereby exposing the plurality of second connectors (pads 621) outside the inspection object. Thereby, the inspection method can fabricate the assembly 70 in which the imaging device 100 of the inspection object and the second connectors face in the same direction, and the second connectors are disposed adjacent to the imaging device 100.

Further, the in plurality of probes 22 are arranged so as to surround the illuminator 23, and, wherein, in the step of (B), in a state in which the plurality of probes 22 are in contact with the plurality of second connectors (pads 621), inspection light is emitted from the illuminator 23 inside the plurality of probes 22 to the imaging device 100 inside the plurality of second connectors. Thereby, in the inspection method, appropriate inspection light can be emitted from the illuminator 23 onto the imaging device 100 within a region inside the plurality of probes 22 and the plurality of second connectors.

Further, in the step of (B), the assembly 70 is placed on a placement surface 31s of a stage 30, and the stage 30 is moved in a horizontal direction and raised upward in a vertical direction to bring the plurality of second connectors (pads 621) into contact with the plurality of probes 22. Thereby, in the inspection method, under the operation of the stage 30, a state in which the second connectors of the assembly 70 are brought into contact with the probes 22, respectively, can be smoothly established.

Further, in the step of (B), a temperature of the assembly 70 is adjusted by a temperature adjustment module 36 provided inside the stage 30. Thereby, in the inspection method, the temperature of the inspection object (wafer W) can be accurately adjusted to a target temperature using the temperature adjustment module 36, and inspection of the inspection object can be performed under precisely adjusted thermal conditions.

Further, at least one of an inspection object side outer peripheral portion of the inspection object (wafer W) outside the imaging device 100 or a jig substrate facing portion of the jig substrate 60 facing the inspection object side outer peripheral portion includes the fixture 71 configured to fix the inspection object and the jig substrate 60, and, wherein, in the step of (A), in a state in which the inspection object side outer peripheral portion and the jig substrate facing portion face each other, the pad (electrode pad 115) of the inspection object and the plurality of first connectors (jig probes 611) are positionally aligned, and the inspection object and the jig substrate 60 are fixed by the fixture 71. Thereby, the inspection method can fabricate the assembly 70 in which the inspection object is accurately positioned relative to the jig substrate 60.

Further, the jig substrate 60 has a recess 60a at a position facing the imaging device 100 of the inspection object (wafer W), and wherein the plurality of first connectors are the plurality of jig probes 611 protruding inside the recess 60a and coming into contact with the pad (electrode pad 115) of the inspection object. According to the above, the inspection method can readily fabricate the assembly 70 in which the wiring layer 114 of the inspection object is in contact with the jig probes 611.

Further, the plurality of jig probes 611 have different protruding lengths or spring forces. Thereby, in the assembly 70B, the contact load applied to the inspection object from the plurality of jig probes 611 can be appropriately adjusted. For example, the assembly 70B can prevent deformation of the inspection object by applying a uniform contact load to the inspection object.

Further, in the assembly 70A, the deformation preventing member 80 configured to prevent deformation of the inspection object (wafer W) and stacked at a position opposite to the jig substrate 60 with the inspection object interposed between the deformation preventing member 80 and the jig substrate 60. By stacking the deformation preventing member 80, the inspection method can prevent deformation of the inspection object due to the contact load and thereby prevent damage or breakage.

Further, a second embodiment of the present disclosure is an inspection apparatus 1 for inspecting an inspection object (wafer W) having an imaging device 100 into which light is introduced from a surface (upper surface Wsa) opposite to a wiring layer 114, the inspection apparatus including a jig substrate 60 including, in one surface (upper surface 60sa), a plurality of first connectors (jig probes 611) and a plurality of second connectors (pads 621), which are electrically connected to the plurality of first connectors, respectively, and disposed adjacent to the plurality of first connectors, wherein the one surface of the jig substrate 60 and a surface (lower surface Wsb) of the inspection object having a pad (electrode pad 115) connected to the wiring layer 114 are fixed to face each other so that the inspection object is formed into an assembly 70 in which the pad (electrode pad 115) and the plurality of first connectors are electrically connected, a stage 30 on which the jig substrate 60 of the assembly 70 is placed, an illuminator 23 configured to emit inspection light onto the inspection object of the assembly 70, a plurality of probes 22 provided adjacent to the illuminator 23 and capable of being brought into contact with the plurality of second connectors, respectively, and a controller (controller 90) configured to control the stage 30 and the illuminator 23, wherein the controller is configured to operate the stage 30 to cause the surface of the inspection object opposite to the wiring layer in the assembly 70 to face the illuminator 23 and to bring the plurality of probes 22 into contact with the plurality of second connectors, respectively, and configured to inspect the inspection object by emitting the inspection light from the illuminator 23 and acquiring an electrical signal of the imaging device 100 via the plurality of probes 22.

Further, a third embodiment of the present disclosure is an inspection system 50 for inspecting an inspection object (wafer W) having an imaging device 100 into which light is introduced from a surface (upper surface Wsa) opposite to a wiring layer 114, the inspection system including a positioning and fixing apparatus 51 configured to fix one surface (upper surface 60sa) of a jig substrate 60, including, in the one surface, a plurality of first connectors (jig probes 611) and a plurality of second connectors (pads 621), which are electrically connected to the plurality of first connectors, respectively, and disposed adjacent to the plurality of first connectors, to a surface (lower surface Wsb) of the inspection object having a pad (electrode pad 115) connected to the wiring layer 114 so as to face each other, thus forming an assembly 70 in which the pad (electrode pad 115) and the plurality of first connectors are electrically connected, and an inspection apparatus 1 configured to inspect the inspection object of the assembly 70, wherein the inspection apparatus 1 includes a stage 30 on which the jig substrate 60 of the assembly 70 is placed, an illuminator 23 configured to emit inspection light onto the inspection object of the assembly 70, a plurality of probes 22 provided adjacent to the illuminator 23 and capable of being brought into contact with the plurality of second connectors, respectively, and a controller (controller 90) configured to control the stage 30 and the illuminator 23, and wherein the controller is configured to operate the stage 30 to cause the surface of the inspection object opposite to the wiring layer in the assembly 70 to face the illuminator 23 and to bring the plurality of probes 22 into contact with the plurality of second connectors, respectively, and configured to inspect the inspection object by emitting the inspection light from the illuminator 23 and acquiring an electrical signal of the imaging device 100 via the plurality of probes 22. In the second and third embodiments as well, inspection of the inspection object can be performed smoothly with a simple configuration.

The inspection method, the inspection apparatus 1, and the inspection system 50 according to the embodiments disclosed herein are illustrative and not restrictive in all respects. The embodiments may be modified and improved in various forms without departing from the scope and spirit of the appended claims. The matters described in the plurality of embodiments may be implemented in other configurations insofar as they do not contradict one another, and may also be combined with each other within a non-contradictory scope.

This application claims priority to Japanese Patent Application No. 2023-183444 filed on October 25, 2023 to the Japan Patent Office, the entire contents of which are incorporated herein by reference.

According to one embodiment, an inspection object having a backside-illuminated imaging device may be smoothly inspected with a simple configuration.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An inspection method for inspecting an inspection object having an imaging device into which light is introduced from a surface opposite to a wiring layer, the inspection method comprising:
(A) forming an assembly by fixing the inspection object and a jig substrate; and
(B) after the step of (A), inspecting the inspection object by emitting inspection light from an illuminator to the imaging device of the inspection object,
wherein the jig substrate includes, in one surface, a plurality of first connectors and a plurality of second connectors, which are electrically connected to the plurality of first connectors, and disposed adjacent to the plurality of first connectors,
wherein, in the step of (A), the assembly is formed by causing a surface of the inspection object having a pad connected to the wiring layer to face the one surface of the jig substrate so that the pad and the plurality of first connectors are electrically connected, and
wherein, in the step of (B), the inspection object is inspected in a state in which the surface of the inspection object opposite to the wiring layer in the assembly faces the illuminator and a plurality of probes disposed adjacent to the illuminator are connected with the plurality of second connectors.

2. The inspection method of claim 1, wherein in the jig substrate, the plurality of second connectors are arranged to surround the plurality of first connectors.

3. The inspection method of claim 2, wherein the jig substrate has a larger planar shape than the inspection object, and
wherein, in the step of (A), the inspection object and the jig substrate are stacked by overlapping the imaging device of the inspection object with respect to the plurality of first connectors, thereby exposing the plurality of second connectors outside the inspection object.

4. The inspection method of claim 3, wherein the plurality of probes are arranged so as to surround the illuminator, and
wherein, in the step of (B), in a state in which the plurality of probes are in contact with the plurality of second connectors, inspection light is emitted from the illuminator inside the plurality of probes to the imaging device inside the plurality of second connectors.

5. The inspection method of claim 4, wherein, in the step of (B), the assembly is placed on a placement surface of a stage, and the stage is moved in a horizontal direction and raised upward in a vertical direction to bring the plurality of second connectors into contact with the plurality of probes.

6. The inspection method of claim 5, wherein, in the step of (B), a temperature of the assembly is adjusted by a temperature adjustment module provided inside the stage.

7. The inspection method of claim 1, wherein, in the step of (B), the assembly is placed on a placement surface of a stage, and the stage is moved in a horizontal direction and raised upward in a vertical direction to bring the plurality of second connectors into contact with the plurality of probes.

8. The inspection method of claim 1, wherein at least one of an inspection object side outer peripheral portion of the inspection object outside the imaging device or a jig substrate facing portion of the jig substrate facing the inspection object side outer peripheral portion includes a fixture configured to fix the inspection object and the jig substrate, and
wherein, in the step of (A), in a state in which the inspection object side outer peripheral portion and the jig substrate facing portion face each other, the pad of the inspection object and the plurality of first connectors are positionally aligned, and the inspection object and the jig substrate are fixed by the fixture.

9. The inspection method of claim 1, wherein the jig substrate has a recess at a position facing the imaging device of the inspection object, and
wherein the plurality of first connectors are a plurality of jig probes protruding inside the recess and coming into contact with the pad of the inspection object.

10. The inspection method of claim 9, wherein the plurality of jig probes have different protruding lengths or spring forces.

11. The inspection method of claim 1, wherein the assembly includes a deformation preventing member configured to prevent deformation of the inspection object and stacked at a position opposite to the jig substrate with the inspection object interposed between the deformation preventing member and the jig substrate.

12. An inspection apparatus for inspecting an inspection object having an imaging device into which light is introduced from a surface opposite to a wiring layer, the inspection apparatus comprising:
a jig substrate including, in one surface, a plurality of first connectors and a plurality of second connectors, which are electrically connected to the plurality of first connectors, and disposed adjacent to the plurality of first connectors,
wherein the one surface of the jig substrate and a surface of the inspection object having a pad connected to the wiring layer are fixed to face each other so that the inspection object is formed into an assembly in which the pad and the plurality of first connectors are electrically connected;
a stage on which the jig substrate of the assembly is placed;
an illuminator configured to emit inspection light onto the inspection object of the assembly;
a plurality of probes provided adjacent to the illuminator and capable of being brought into contact with the plurality of second connectors; and
a controller configured to control the stage and the illuminator,
wherein the controller is configured to operate the stage to cause the surface of the inspection object opposite to the wiring layer in the assembly to face the illuminator and to bring the plurality of probes into contact with the plurality of second connectors, and configured to inspect the inspection object by emitting the inspection light from the illuminator and acquiring an electrical signal of the imaging device via the plurality of probes.

13. An inspection system for inspecting an inspection object having an imaging device into which light is introduced from a surface opposite to a wiring layer, the inspection system comprising:
a positioning and fixing apparatus configured to fix one surface of a jig substrate to a surface of the inspection object to face each other to form an assembly,
wherein the jig substrate includes, in the one surface, a plurality of first connectors and a plurality of second connectors, which are electrically connected to the plurality of first connectors, and disposed adjacent to the plurality of first connectors,
wherein the surface of the inspection object has a pad connected to the wiring layer, and
wherein the assembly is formed by electrically connecting the pad and the plurality of first connectors; and
an inspection apparatus configured to inspect the inspection object of the assembly,
wherein the inspection apparatus includes:
a stage on which the jig substrate of the assembly is placed;
an illuminator configured to emit inspection light onto the inspection object of the assembly;
a plurality of probes provided adjacent to the illuminator and capable of being brought into contact with the plurality of second connectors, respectively; and
a controller configured to control the stage and the illuminator, and
wherein the controller is configured to operate the stage to cause the surface of the inspection object opposite to the wiring layer in the assembly to face the illuminator and to bring the plurality of probes into contact with the plurality of second connectors, respectively, and configured to inspect the inspection object by emitting the inspection light from the illuminator and acquiring an electrical signal of the imaging device via the plurality of probes.
